(19) United States
(12) Patent Application Publication
(10) Pub. No.: US 2006/0181361 A1
(43) Pub. Date: Aug. 17, 2006

(54) Accurate untrimmed crystal oscillator

(75) Inventors: Marcel Van De Gevel, Haarlem (NL); Onno Marcel Kuijken, Nijmegen (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronices N.V.

(21) Appl. No.: 10/565,145

(22) PCT Filed: Jul. 16, 2004
(86) PCT No.: PCT/IB04/51246

§ 371 Date: Jan. 19, 2006

(30) Foreign Application Priority Data
Jul. 22, 2003 (EP) 03102250.2

(51) Int. Cl. H03B 5/32

(52) U.S. Cl. 331/158

(57) ABSTRACT

The present invention relates to a crystal oscillator for generating an oscillator signal having a predetermined frequency, wherein a frequency-dependent negative resistance circuit (FDNR) having a negative resistance inversely proportional to frequency squared is connected to an oscillator crystal (Q). Thereby, the voltage across the crystal (Q) approaches the time integral of a current supplied by an amplitude control means (10) and the input voltage of the amplitude control means (10) approaches the time integral of the current flowing through the crystal (Q). Due to this integration behavior of the frequency-dependent negative resistance circuit (FDNR), no accurate capacitors or other accurate reactive components are necessary. High accuracy can thus be achieved without trimming As an example, the frequency-dependent negative resistance circuit may comprise a first integrator circuit having an output connected to the oscillator crystal (Q), a second integrator circuit having an input connected to the crystal (Q), and an amplifier circuit used for controlling the amplitude.

The present invention relates to a crystal oscillator for generating an oscillator signal having a predetermined frequency, and in particular to a fundamental mode crystal oscillator which operates at the series resonant frequency.

Crystal oscillators are widely used in electronic circuits requiring an accurate frequency or time reference. Examples are test and measurement equipment, electronic clocks, and communications equipment including all kinds of broadcast receivers. For reasons of costs and size, it is often desirable to avoid trimming and to avoid using any accurate components other than the crystal itself. Inaccurate components can be monolithically integrated, thereby reducing the size and, if produced in large numbers, costs of the circuit.

Fundamental mode crystal oscillators are usually of the Pierce type or of the series resonant type. A Pierce oscillator is described, for example, in Janusz Groszkowski, “Frequency of self-oscillations”, Panstwowe Wydawnictwo Naukowe, Warszawa and Pergamon Press, Oxford, London, New York and Paris, 1964. In this document, Pierce oscillators are referred to as ga-oscillators. Furthermore, oscillators of the Pierce type and of the series resonant type are described in C. A. M. Boon, “Design of high-performance negative-feedback oscillators”, Ph. D. thesis, Delft University of Technology, 1989. Information about series resonant crystal oscillators can also be found in E. H. Nordholt, et al., “A systematic approach to the design of single-pin integrated crystal oscillators”, 30^{th} Midwest symposium on circuits and systems, 1988.

In the following, the phrase “Pierce oscillator” is used to designate any oscillator comprising a crystal, capacitors, and some kind of transconductance amplifier, regardless of the precise implementation of or number of active devices used in the transconductance amplifier.

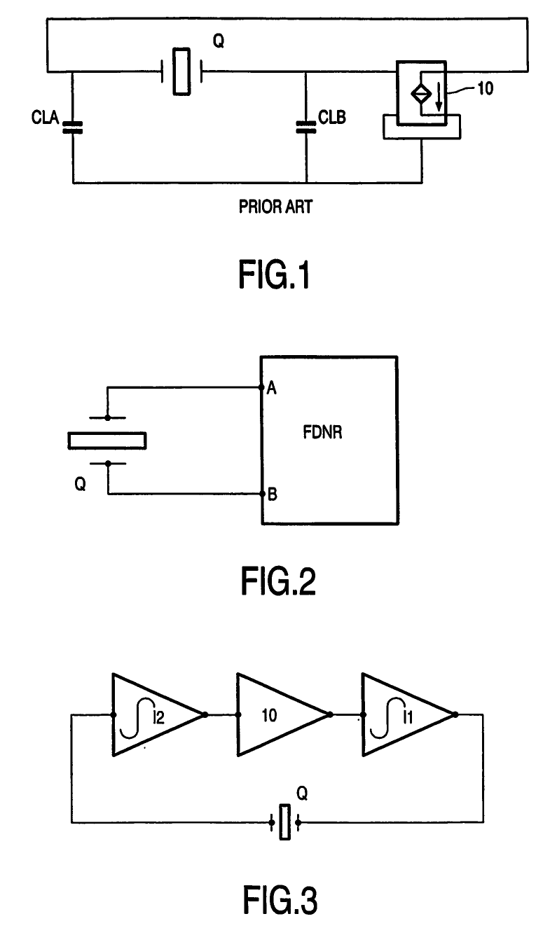

FIG. 1 shows a generalized schematic circuit diagram of a Pierce oscillator comprising a crystal Q as a frequency-determining element, and two capacitors CLA, CLB which have to be accurate or trimmed to obtain good frequency accuracy of the oscillator circuit. Furthermore, a transconductance amplifier 10 is provided to amplify the oscillation signal for feedback to the crystal Q. Oscillation occurs when the transconductance value is chosen such that the well-known Nyquist stability criterion is not satisfied. Oscillation builds up from zero when power is first applied, under linear circuit operation. However, limiting amplifier saturation and other non-linear effects or amplitude control functions of the transconductance amplifier 10 end up keeping the Pierce oscillator's amplitude from building up indefinitely.

Crystal oscillators are usually fixed frequency oscillators where stability and accuracy are the primary considerations. The transconductance amplifier 10 provides an output current which is proportional to its input voltage, meaning that it takes a voltage difference input and produces a current drive output supplied via the feedback circuitry to the crystal Q. Thereby, lost energy can be re-supplied to the crystal Q while putting little load on it.

In the conventional Pierce oscillator as shown in FIG. 1, the combination of the crystal Q and the series connection of the two capacitors CLA and CLB sets the frequency of the oscillation signal, wherein the value of the two series capacities is known as the load capacitance. This is a clear disadvantage when high accuracy is required without trimming and without using highly accurate capacitors. The sensitivity of the frequency to the load capacitance can be reduced by increasing the load capacitance. However, this is disadvantageous for IC implementations as it requires a lot of chip area. As an example, hundreds of picofarads may be required if the influence of the 10% to 20% tolerance of a typical integrated capacitor is to be reduced to a few ppm (parts per million) of frequency error. Also, the larger the load capacitance, the larger the required undamping transconductance, which is not convenient if the supply current has to be kept low.

Due to the filtering effect of the two load capacitors CLA and CLB, Pierce oscillators are less likely to burst into oscillations at overtones of the crystal Q than series oscillators. This filtering effect also reduces the frequency shift due to harmonics generated in the non-linear transconductance amplifier 10 substantially.

In contrast to Pierce oscillators, series resonant crystal oscillators consisting of a crystal and some type of negative resistance circuit do not have the problem of trimming and accurate components. However, the combination of the negative resistance and the positive parallel capacitance of the crystal results in a pole in the right half portion of the complex plane, which tends to cause parasitic relaxation oscillations. Besides, these oscillators are also more susceptible to undesired oscillations at overtones. The relaxation oscillations can be eliminated by reducing the bandwidth of the negative resistance circuit, which however again effects the frequency accuracy. The oscillation frequency of series crystal oscillators is also more sensitive to the influence of the harmonics which are generated when clipping is used to control the amplitude. Using the harmonic balance method, Janusz Groszkowski has shown that the frequency error in a Pierce oscillator depends on harmonic distortion in the current coming out of the transconductance amplifier 10. With a conventional series oscillator, the frequency error due to non-linearity becomes excessive if the amplitude is determined by a hard clipping amplifier and if there is no bandwidth limiting circuit to attenuate the high harmonics. Due to the absence of the filtering effect achieved by the capacitors CLA and CLB in FIG. 1, the third harmonic has nine times as much influence as in a Pierce oscillator, the fifth harmonic 25 times as much, the seventh harmonic 49 times as much, and so on.

An unusual parallel resonance crystal oscillator is proposed in David Ruffieux, “A high-stability, ultra-low-power differential oscillator circuit for demanding radio applications”, ESSCIRC 2002, pp. 85 to 88, 2002. This document refers, among other things, to document EP 01 202 173. This parallel resonant crystal oscillator operates very close to the crystal parallel resonance with zero load capacitance. Although this circuit seems very promising for low-power applications, it can only achieve a high untrimmed accuracy if the chip, package and PCB parasitic capacitances are either accurate or much smaller than the crystal's static capacitance C₀. This could make the PCB design problematic. Furthermore, the crystal manufacturer has to guarantee the crystal's accuracy for near-zero load capacitances. Most crystal manufacturers only supply accurate crystals for use with load capacitances well above C₀ and for series resonance.

It is an object of the present invention to provide a highly accurate crystal oscillator which does not require trimming.

This object is achieved by a crystal oscillator as defined in claim 1. Accordingly, the proposed crystal oscillator accurately operates at series resonant frequency without relaxation oscillation problem and with an equally low sensitivity to harmonics and overtones as the Pierce oscillator. It does not require any accurate or large capacitors or other accurate components other than the crystal, and is therefore very suitable for monolithic integration. The circuit can be designed to be reasonably tolerant to PCB parasitics.

As an example, the frequency-dependent negative resistance circuit may comprise a first integrator circuit having an output connected to the crystal, a second integrator circuit having an input connected to the crystal and an amplifier. The output of the first integrator circuit may be a low-impedance voltage output, and the input of the second integrator circuit may be a low-impedance current input, good matching to the low series resonant impedance of the crystal can be achieved. Hence, the integrators in the frequency-dependent negative resistance circuit behave as capacitors with infinite capacitance, so that the oscillation frequency approaches the series resonant frequency, the voltage across the crystal approaches the time integral of the current supplied by amplifier circuit, and the input voltage of the amplifier circuit approaches the time integral of the current flowing through the crystal. In fact, this means that the circuit has a negative resistance which drops with the square of the frequency, but which has no reactive part. When the amplifier circuit clips, the resistance becomes zero, again without any reactive part. Hence, the only accurate component required is the crystal itself.

The amplifier circuit may be a clipping amplifier circuit or a gain-controlled amplifier circuit. In particular, the amplifier circuit may be a transconductance amplifier.

At least one direct current feedback loop may be provided for biasing the first and second integrator circuits. This direct current feedback loop serves to keep the first and second integrators properly biased. As an example, the direct current feedback loop may comprise a resistor connected in parallel with the crystal to thereby achieve a simple implementation.

The amplifier circuit may comprise a differential pair of transistor means to thereby achieve a simple implementation.

The first and second integrator circuits may comprise a single-stage integrating transimpedance amplifier with a feedback capacitor. As an alternative, a two-stage integrating transimpedance amplifier with a feedback capacitor may be used. In this case, a first transistor element of the output stage of the two-stage integrating transimpedance amplifier may be biased by a second transistor element. Furthermore, resistor means may be connected in series with the feedback capacitor to provide additional phase compensation. Of course, integrator implementations with more than two stages are possible as well.

The crystal oscillator may have a single-pin configuration, where one terminal of the crystal is connected to a reference potential. As an alternative, the crystal oscillator may as well have a two-pin configuration. In both cases, an anti-latch-up circuit can be provided for preventing an undesirable stable bias point of the amplifier circuit.

The present invention will now be described in greater detail based on preferred embodiments with reference to the accompanying drawings, in which:

FIG. 1 shows a schematic circuit diagram of a conventional Pierce oscillator;

FIG. 2 shows a generalized schematic block diagram of a crystal oscillator according to the present invention;

FIG. 3 shows a schematic block diagram of a crystal oscillator according to an example relating to the preferred embodiments;

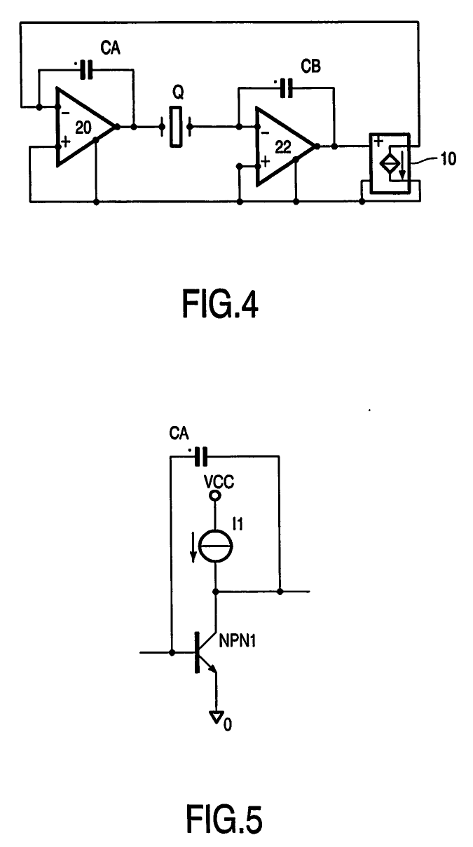

FIG. 4 shows a more specific circuit diagram of a crystal oscillator according to the preferred embodiments;

FIG. 5 shows a schematic circuit diagram of a single-stage integrator circuit as can be used in the preferred embodiments;

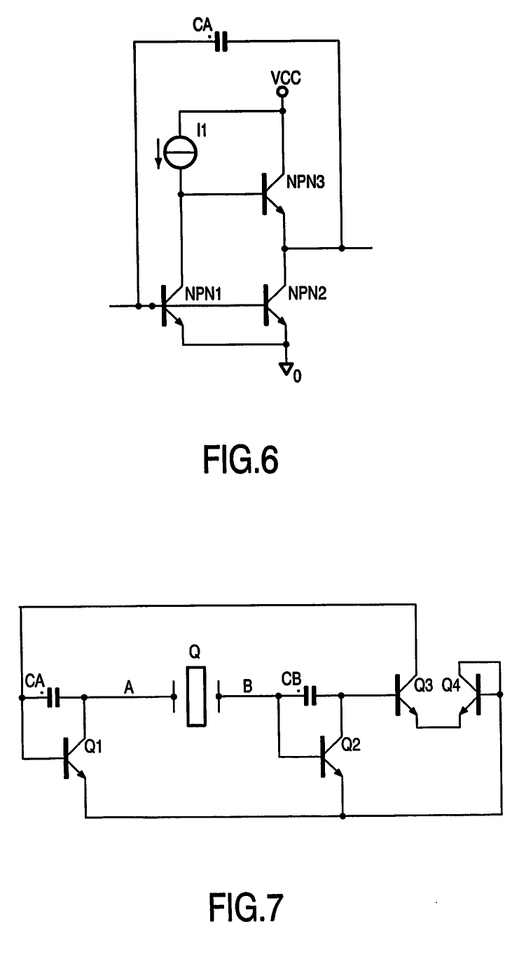

FIG. 6 shows a schematic circuit diagram of a simple two-stage integrator circuit as can be used in the preferred embodiments;

FIG. 7 shows a schematic circuit diagram of a crystal oscillator according to the first preferred embodiment;

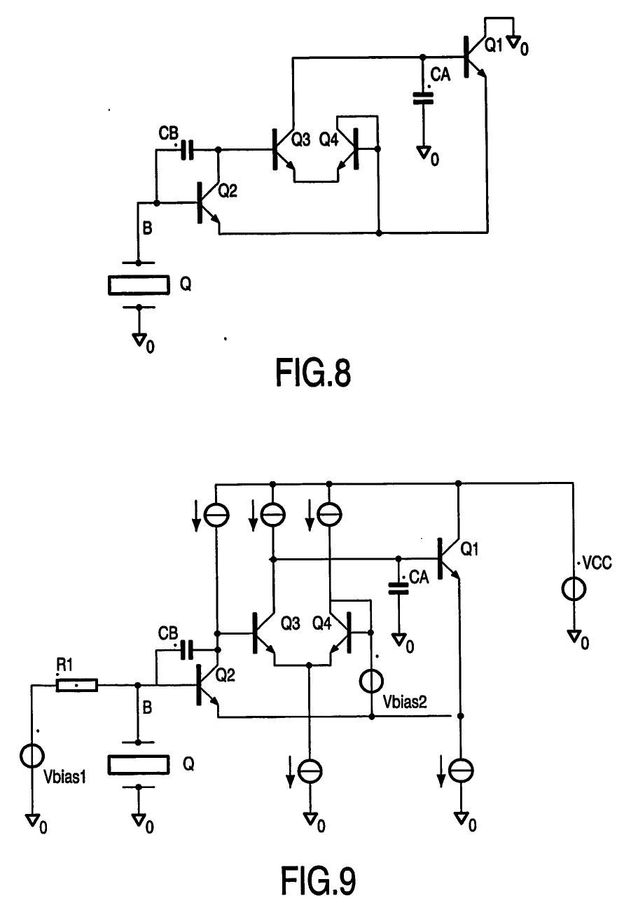

FIG. 8 shows a schematic circuit diagram of a crystal oscillator according to the second preferred embodiment;

FIG. 9 shows a more detailed circuit diagram of the second preferred embodiment with a biasing circuitry;

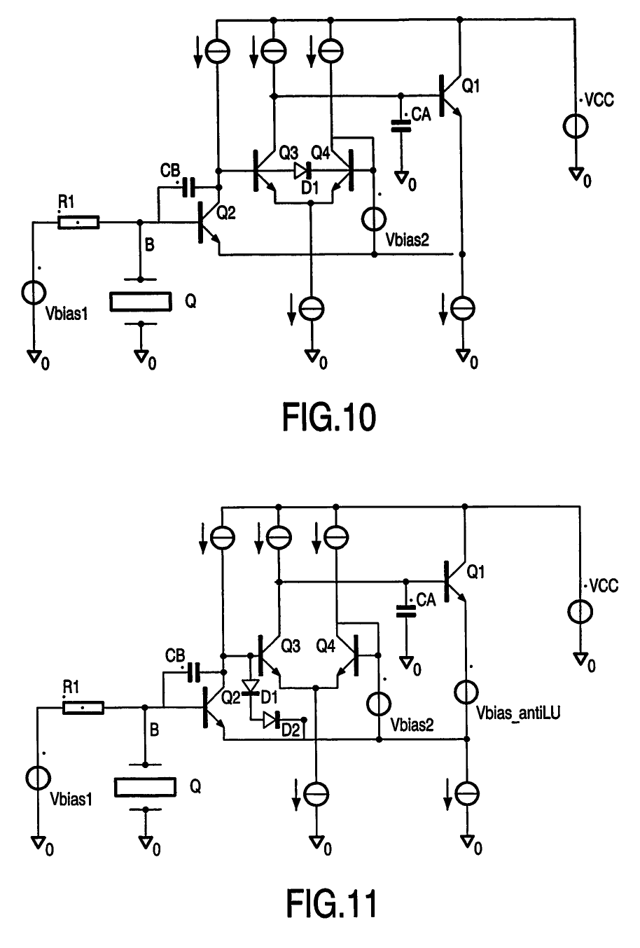

FIG. 10 shows a more detailed circuit diagram of the second preferred embodiment with anti-latch-up circuitry;

FIG. 11 shows a more detailed circuit diagram of the second preferred embodiment with an alternative anti-latch-up circuitry;

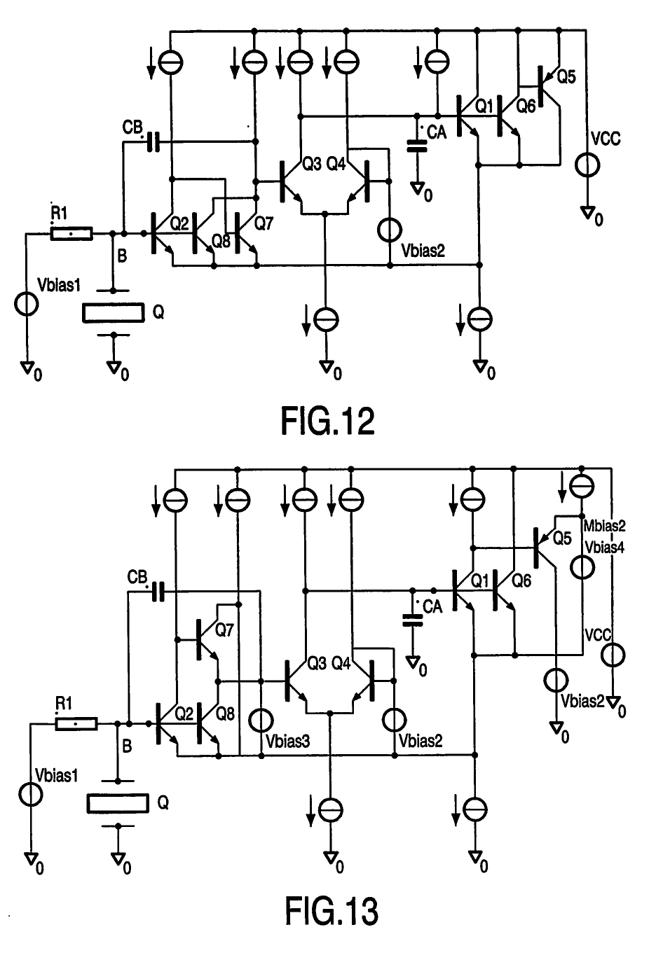

FIG. 12 shows a schematic circuit diagram of a crystal oscillator according to a third preferred embodiment with two-stage integrators;

FIG. 13 shows a schematic circuit diagram of a crystal oscillator according to a fourth preferred embodiment with a different two-stage integrator arrangement;

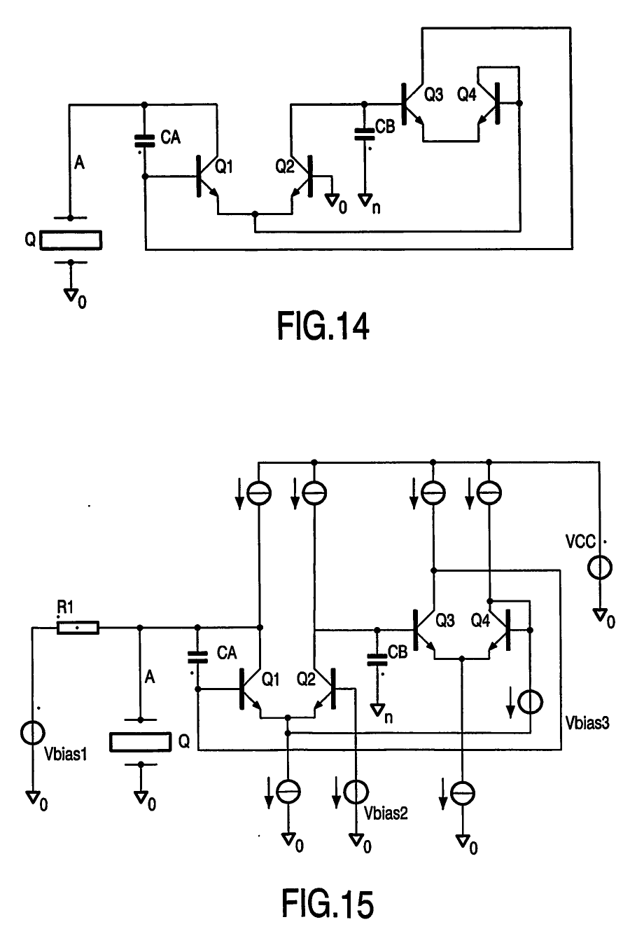

FIG. 14 shows a schematic circuit diagram of a crystal oscillator according to a fifth preferred embodiment with alternative single-pin version; and

FIG. 15 shows a more detailed circuit diagram of the fifth preferred embodiment with biasing circuitry.

In the present invention, an alternative series resonant oscillator is provided which retains some of the advantages of a Pierce oscillator. It is supposed that the load capacitors CLA and CLB of the Pierce oscillator of FIG. 1 are made extremely large and the transconductance G of the transconductance amplifier 10 is increased accordingly. As the load capacitance is increased, the oscillation frequency moves closer and closer to the series resonant frequency and the sensitivity to the load capacitors CLA and CLB decreases. When the first load capacitor CLA is made extremely large, its reactance becomes very small and almost all of the output current of the transconductance amplifier 10 will flow through the first capacitor CLA. As a result, the voltage across the first load capacitor CLA will be approximately equal to the time integral of the current supplied by the transconductance amplifier 10, divided by the capacitance of the first load capacitor CLA. This approximation becomes more accurate as the capacitance of the first load capacitor CLA as increased. Similarly, as the second load capacitor CLB becomes larger, the voltage across the second load capacitor CLB drops and the voltage across the crystal Q gets closer and closer to the voltage across the first load capacitor CLA. The voltage across the second load capacitor CLB always equals the time integral of the current through the crystal Q, divided by the capacitance of the second load capacitor CLB.

Therefore, if the capacitances of the first and second load capacitors CLA and CLB are increased towards infinity, i.e. CLA→∞ and CLB→∞, the oscillation frequency approaches the series resonant frequency, the voltage across the crystal Q approaches the time integral of the current output by the non-linear transconductance amplifier 10, and the input voltage of the transconductance amplifier 10 approaches the time integral of the current flowing through the crystal Q.

According to the present invention, such a behavior can be realized with the circuit shown in FIG. 2 without requiring any infinite capacitors or infinite transconductance. In fact, the circuit of FIG. 2 has a frequency-dependent negative resistance circuit FDNR with a resistance which drops with the square of the frequency, but which has no reactive part. If clipping is used to control the amplitude, the impedance of the FDNR should become small, ideally zero, during clipping, again ideally without any reactive part.

If the crystal Q in the Pierce oscillator of FIG. 1 is replaced by an independent current source, the voltage V_{CLB} across the second load capacitor CLB will be proportional to the time integral of the current i coming out of the current source. As long as the transconductance amplifier 10 doesn't clip, the same applies to the amplifier's output current i_{tc}. The voltage v_{CLA} across the first load capacitor CLA will then be proportional to the sum of the time integral of the current coming out of the transconductance amplifier 10 and the time integral of the current of the independent current source. This can be expressed by the following equations:
v_{CLB}=∫idt/CLB (1)
i_{tc}=−G*∫idt/CLB (2)
v_{CLA}=(∫−idt/CLA)+(∫(−G*∫idt/CLB)dt/CLA) (3)
where G denotes the transconductance of the transconductance amplifier 10 and CLA and CLB designate the capacitance values of the first and second load capacitors CLA, CLB, respectively.

The same stated in the Laplace domain, where s=Jω=j2πf:
V_{CLB}=I/(s*CLB) (4)
I_{tc}=−G*I/(s*CLB) (5)
V_{CLA}=−I/(s*CLA)−G*I/(sˆ2*CLA*CLB) (6)

Hence, the impedance between the crystal terminals with the crystal Q disconnected equals:
Z=(V_{CLB}−V_{CLA})/I=1(s*CLB)+1/(s*CLA)+G/(sˆ2*CLA*CLB) (7)

If clipping is used to control the oscillation amplitude, the impedance changes to
Z=1/(s*CLB)+1/(s*CLA) (8)
when the transconductance amplifier 10 clips.

In a Pierce oscillator, the frequency is set by the combination of the crystal Q and the capacitors CLA and CLB. As already mentioned, this is a clear disadvantage when high accuracy is required without trimming and without using highly accurate capacitors. Theoretically, the sensitivity to CLA and CLB approaches zero for CLA and CLB approaching infinity, and the oscillation frequency approaches the (unloaded) series resonant frequency of the crystal.

Looking at equations (7) and (8), increasing CLA and CLB more and more and increasing G accordingly to keep the undamping term (last term) in equation (7) constant, makes the impedances in equations (7) and (8) approach the following values:

When the transconductance amplifier 10 doesn't clip:
Z=K/sˆ2 (9)
where K is a constant.

When the transconductance amplifier 10 does clip:
Z=0 (10)

Substituting s=j2πf into equation (9) proves that this equation defines a frequency-dependent negative resistance (jˆ2=−1), the resistance being inversely proportional to frequency squared.

Hence, a crystal oscillator operating at the series resonant frequency of the crystal without any need for trimming or for accurate capacitors can be made by connecting the frequency-dependent negative resistance circuit FDNR complying with equation (9) to the crystal Q. Due to the frequency dependence in equation (9), the negative resistance circuit FDNR will have an equally small sensitivity to overtone resonances of the crystal as a normal Pierce oscillator. Some means of amplitude control will have to be provided, either by a slow amplitude control loop controlling factor K in equation (9), or by some clipping mechanism switching the impedance between the values indicated in equations (9) and (10).

Frequency-dependent negative resistance circuits whose resistance is inversely proportional to frequency squared are frequently used in filter circuits. However, the most common implementations for filters are not suitable for crystal oscillators as they are neither controllable, nor do they have a suitable clipping behavior. Negative resistance circuits commonly used in oscillators are controllable or have suitable clipping behavior, but their resistance is not inversely proportional to the square of the frequency.

The preferred embodiments will now be described on the basis of a crystal oscillator as shown in FIG. 3, wherein a crystal Q is included in a filter circuit comprising two integrators I1 and I2 and an amplifier 10 as the frequency-dependent negative resistance circuit.

The circuit in FIG. 3 does have the above proper properties of the negative resistance circuit FDNR. In FIG. 3, the frequency-dependent negative resistance circuit comprises two integrators I1 and I2. Furthermore, an amplifier 10 is provided to undamp the filter. Usually, the oscillation amplitude is set by non-linearity of the amplifier 10, although it is as well possible to use an amplitude control loop for defining the oscillation amplitude. The left-hand integrator I2 has a low impedance current input and the right-hand integrator I1 has a low impedance voltage output. It is assumed that the crystal Q in FIG. 3 is replaced by an independent current source. The output signal of the left-hand integrator I2 will be proportional to the time integral of the current coming out of the current source. As long as the amplifier doesn't clip, the same applies to the output signal of the amplifier 10. The output voltage of the right-hand integrator I1 then becomes proportional to the double time integral of the current. Because of the low impedance of the input of the left-hand integrator I2, the voltage across the current source nearly equals the output voltage of the right-hand integrator I1, and is therefore proportional to the double time integral of the current.

Stated in terms of impedances, this means that the impedance between the crystal Q terminals with the crystal disconnected is
Z=K/sˆ2, (11)
where K is a constant depending on the construction of the integrators I1, I2 and the amplifier 10. This is exactly the impedance required by equation (9). When the amplifier 10 clips, the impedance becomes the sum of the output impedance of the right-hand integrator I1 and the input impedance of the left-hand integrator I2. This is a small, ideally zero, impedance. If clipping is used to control the amplitude, due to the double integration in FIG. 2, the sensitivity of the oscillation frequency to the harmonics generated in the clipping amplifier 10 is equally small as in a Pierce oscillator.

Obviously, any other circuit having the same behavior at its terminals would be equally suited for an accurate crystal oscillator.

The first and second integrators I1 and I2 shown in FIG. 3 can be implemented, e.g., as integrator circuits with operational amplifiers and feedback capacitors.

In general, the first integrator I1 of FIG. 3 can be an integrator with a low-impedance voltage output, and the second integrator I2 of FIG. 3 can be an integrator with a low-impedance current input. The amplifier 10 of FIG. 3 can be any amplifier which controls the amplitude either by clipping or by having its gain controlled by a separate amplitude control loop. Depending on the output quantity of the second integrator I2, e.g. voltage, current or power, and the input quantity of the first integrator I1, e.g. voltage, current or power, the controlled or clipping amplifier 10 can be a transconductance, transimpedance, voltage, current, power, voltage to power, current to power, power to voltage, or power to current amplifier. Furthermore, some form of direct current (DC) feedback can be provided to keep the first and second integrators I1, I2 properly biased. This can be achieved, for example, with separate DC feedback loops around each integrator or with some overall DC feedback loop. The simplest implementation may be a large resistor (not shown) in parallel with the crystal Q.

FIG. 4 shows a more specific or practical generalized circuit diagram with two integrator circuits consisting of two operational amplifiers 20, 22 and respective feedback capacitors CA and CB. Furthermore, a transconductance amplifier 10 as indicated in FIG. 1 is used. The practical implementation shown in FIG. 4 consists of integrators with current input and voltage output and a clipping transconductance amplifier 10. The simplest embodiment of the clipping transconductance amplifier 10 is a simple differential pair of active elements, e.g. bipolar transistors. However, more elaborate clipping circuits can also be used.

FIGS. 5 and 6 show two straightforward examples of the integrators I1 and I2 of FIG. 3. FIG. 5 shows a simple single-stage integrating transimpedance amplifier comprising an npn transistor NPN1, a feedback capacitor CA and a current source for generating a biasing current I1.

Furthermore, FIG. 6 shows a two-stage version of the first and second integrators I1 and I2, wherein additional second and third npn transistors NPN2 and NPN3 are provided. As in FIG. 5, the current source for generating the biasing current I1 is connected to the power supply voltage VCC, while the first npn transistor NPN1 is connected to ground. The second npn transistor NPN2 takes care of the biasing of the third npn transistor NPN3 which is an output stage transistor, while simultaneously providing a kind of multi-path frequency compensation. The base terminals of the first and second npn transistors NPN1 and NPN2 are both connected to the input terminal of the integrator. The bipolar transistors can be replaced by other active devices, such as MOSFETs (Metal Oxide Semiconductor Field Effect Transistors), JFETs (Junction FETs), HEMTs (High Electron Mobility Transistors), GaAsFETs (Gallium Arsenide FETs) or thermionic valves. In both circuits of FIGS. 4 and 5, a small resistor can be connected in series with the feedback capacitor to provide additional phase compensation.

As mentioned earlier, the small-signal impedance between the crystal pins with the crystal Q disconnected is a frequency-dependent negative resistance, decreasing with the square of the frequency. Other frequency-dependent negative resistor implementations may be suitable as well for use in the proposed crystal oscillator, provided they can either be controlled by an amplitude control loop or be made to clip cleanly and provide a small, preferably resistive impedance when clipping.

Furthermore, it should be noted that the crystal oscillator according to the present invention may as well be implemented in a so-called single-pin crystal oscillator configuration. In such a single-pin crystal oscillator configuration, by definition, one of the crystal pins is connected to ground, to a power supply voltage, or to any other fixed reference potential. With suitably designed integrators I1 and I2, one of the crystal pins of the crystal Q in FIG. 4 can be connected to ground or to the supply voltage.

In the following, first to fifth embodiments of the present invention are described in more detail based on FIGS. 7 to 15.

FIG. 7 shows a schematic circuit diagram of a crystal oscillator according to a first preferred embodiment, where the first and second integrators I1, I2 correspond to the single-stage integrator shown in FIG. 5. It is noted that the biasing circuitry has been omitted in FIG. 7 for reasons of simplicity. The first integrator comprises a first transistor Q1 with a feedback capacitance CA, and the second integrator comprises a second transistor Q2 with a corresponding second feedback capacitor CB. The transconductance amplifier 10 is implemented by a simple differential pair of transistors Q3 and Q4 and thus corresponds to a clipping amplifier with soft limiting functionality.

As already mentioned, the crystal oscillator according to the present invention may also be implemented as a single-pin oscillator. In such a single-pin oscillator, one of the crystal pins is connected to ground or to power supply voltage VCC. The second to fifth embodiments shown in FIGS. 8 to 15 correspond to different examples of such a single-pin crystal oscillator. For simplicity, the transconductance or clipping amplifier is shown as a simple differential pair and the active parts of the integrators are implemented as single transistors. However, it is noted that more elaborate implementations can also be used. As an example, two-stage integrators are shown in FIGS. 11 and 12.

FIG. 8 shows a crystal oscillator according to a second preferred embodiment as a first single-pin version with the crystal electrode or node A grounded. Consequently, the collector terminal of the transistor Q1 of the first integrator and one terminal of the feedback capacitor CA of the first integrator are also connected to ground so as to provide the corresponding connection to the crystal Q via ground. The second integrator comprises the second transistor Q2 with the feedback capacitor CB. It is noted that in FIG. 8, the biasing circuitry has been omitted.

FIG. 9 shows a more detailed circuit diagram of the second preferred embodiment with biasing circuitry. The biasing circuitry consists of respective current sources and voltage sources Vbias1 and Vbias2. The resistor R1 connected between the crystal Q and the first voltage source Vbias1 may have a relatively high resistance value, which is desirable to prevent conditional stability. It is noted that the current sources indicated in FIG. 9 and in the following figs. may be implemented by any suitable circuitry for achieving a constant current supply.

FIG. 10 shows a more specific circuit diagram of the second preferred embodiment with biasing circuitry and additional anti-latch-up circuitry. The anti-latch-up circuitry of FIG. 10 is implemented by connecting a diode D1 between the base terminals of the differential transistors Q3 and Q4 of the clipping amplifier. An undesirable stable bias point, usually referred to as “latch-up”, occurs when the third transistor Q3 of the differential pair saturates. This saturation can be prevented by the diode D1. In this case, the voltage of the second biasing voltage source, Vbias2 must be smaller than the threshold voltage VBE between the base and emitter of the fourth transistor Q4.

FIG. 11 shows another more specific circuit diagram of the second preferred embodiment with biasing circuitry and an alternative anti-latch-up circuitry consisting of diodes D1 and D2 and an additional voltage source Vbias_antiLU. This anti-latch-up circuitry limits the voltage between the base terminal of the third transistor Q3 and the reference terminal of the second biasing voltage source Vbias2. In this case, the voltage of the second biasing voltage source Vbias2 may correspond to the threshold voltage VBE between the base terminal and the emitter terminal of the fourth transistor Q4.

FIG. 12 shows a schematic circuit diagram of the third preferred embodiment which corresponds to the second preferred embodiment of FIG. 9 except for the integrator circuits. In particular, the single-stage integrator circuits of FIG. 9 have been replaced by two-stage integrator circuits. The first integrator circuit now consists of the first transistor Q1 and additional fifth and sixth transistors Q5 and Q6 with a corresponding current source similar to the circuit diagram of FIG. 6. Furthermore, the second integrator circuit now comprises the second transistor Q2 and additional seventh and eighth transistors Q7 and Q8 with a corresponding additional current source. It is noted that the anti-latch-up circuitries of FIGS. 10 and 11 have been omitted here.

FIG. 13 shows a schematic circuit diagram of a fourth preferred embodiment which corresponds to the second preferred embodiment of FIG. 9 with different two-stage integrator arrangements. Here, additional biasing voltage sources Vbias3, Vbias4 and Vbias5 are provided for biasing the first and second integrators. Additionally, a biasing current source Mbias4 is provided. Due to the fact that the seventh transistor Q7 is an npn transistor, an anti-latch-up circuitry may in fact not be necessary if the voltage of the third biasing voltage source is made small enough. Moreover, the voltage values or, respectively, current values of the biasing sources Vbias4, Mbias4 and Vbias5 can be set to zero if the voltage of the first biasing voltage source Vbias1 equals 1.5 VBE and the signal swings are made sufficiently small.

FIG. 14 shows a schematic circuit diagram of a crystal oscillator with an alternative single-pin-version according to the fifth preferred embodiment. Here, the other crystal electrode or node B is grounded. Thus the remaining circuitry has to be modified correspondingly, as shown in FIG. 14. In particular, the components of the second integrator, i.e. second transistor Q2 and second feedback capacitor CB are now grounded. Again, any biasing or anti-latch-up circuitry has been omitted here.

FIG. 15 shows a more specific circuit diagram of the fifth preferred embodiment with biasing circuitry included. Due to the modified arrangement, three biasing voltage sources Vbias1, Vbias2 and Vbias3 are now provided. When the resistance value of the resistor R1 has a relatively high value, as desired to prevent conditional stability, the biasing becomes very dependent on the matching of sourcing and sinking bias current sources.

It is noted that the present invention is not restricted to the above specific circuit diagrams of the first to fifth preferred embodiments and can be modified in any respect within the basic principles indicated in FIGS. 2 to 4. The preferred embodiments may thus vary within the scope of the attached claims.

1. A crystal oscillator for generating an oscillator signal having a predetermined frequency, said crystal oscillator comprising:
a) a crystal (Q) for determining said predetermined frequency;
b) a frequency-dependent negative resistance circuit (FDNR) connected to said crystal (Q) and having a negative resistance inversely proportional to frequency squared; and
c) means (10) for controlling the amplitude of said oscillator signal, either by a clipping mechanism inside the frequency-dependent negative resistance circuit (FDNR), or by an amplitude control loop controlling the value of the frequency-dependent negative resistance.

2. An oscillator according to claim 1, wherein said frequency-dependent negative resistance circuit comprises a first integrator circuit (I1) having an output connected to said crystal (Q), a second integrator circuit (I2) having an input connected to said crystal (Q), and an amplifier circuit (10) for controlling the amplitude of said oscillator signal.

3. An oscillator according to claim 2, wherein said output of said first integrator circuit (I1) is a low-impedance voltage output, and said input of said second integrator circuit (I2) is a low-impedance current input.

4. An oscillator according to claim 2, wherein said amplifier circuit (10) is a clipping amplifier circuit or a gain-controlled amplifier circuit.

5. An oscillator according to claim 4, wherein said amplifier circuit comprises a transconductance amplifier.

6. An oscillator according to claim 1, further comprising at least one direct current feedback loop for biasing said first and second integrator circuits (I1, I2).

7. An oscillator according to claim 6, wherein said direct current feedback loop comprises a resistor (R1) connected in parallel with said crystal (Q).

8. An oscillator according to claim 2, wherein said amplifier circuit (10) comprises a differential pair of transistor means (Q3, Q4).

9. An oscillator according to claim 2, wherein said first and second integrator circuits (I1, I2) comprise a single-stage integrating transimpedance amplifier with a feedback capacitor (CA, CB).

10. An oscillator according to claim 2, wherein said first and second integrator circuits (I1, I2) comprise a two-stage integrating transimpedance amplifier with a feedback capacitor (CA, CB).

11. An oscillator according to claim 10, wherein a first transistor element (NPN3) of the output stage of said two-stage integrating transimpedance amplifier is biased by a second transistor element (NPN2).

12. An oscillator according to claim 9, further comprising resistor means connected in series with said feedback capacitor (CA, CB).

13. An oscillator according to claim 1, wherein said crystal oscillator has a single-pin configuration, where one terminal of said crystal (Q) is connected to a reference potential.

14. An oscillator according to claim 1, wherein said crystal oscillator has a two-pin configuration.

15. An oscillator according to claim 1, further comprising an anti-latch-up circuit (D1, D1, D2) for preventing an undesirable stable bias point of said amplifier circuit (10).
